(19) United States
(12) Patent Application Publication
(10) Pub. No.: US 2021/0194070 A1
(43) Pub. Date: Jun. 24, 2021

(54) DIAGNOSIS OF BATTERIES

(71) Applicant: RHEINISCH-WESTFÄLISCHE TECHNISCHE HOCHSCHULE (RWTH) AACHEN, Aachen (DE)

(72) Inventor: Alexander GITIS, Aachen (DE)

(73) Assignee: RHEINISCH-WESTFÄLISCHE TECHNISCHE HOCHSCHULE (RWTH) AACHEN, Aachen (DE)

(21) Appl. No.: 16/498,614

(22) PCT Filed: Mar. 27, 2018
(86) PCT No.: PCT/EP2018/057726

§ 371 Date: Sep. 27, 2019

(30) Foreign Application Priority Data
Mar. 31, 2017 (DE) 102017205561.8

(51) Int. Cl. H01M 10/42; H01M 10/48; G01R 31/36; G01N 29/11; G01R 31/28

(52) U.S. Cl. CPC H01M 10/4285; H01M 10/48; G01N 2291/048; G01N 29/11; G01R 31/28; G01R 31/36

(57) ABSTRACT

A diagnostic device for critical changes in batteries having multi-layered structures, a battery system including the diagnostic device, and a method of use thereof. The device determines critical changes relative to a target state in battery cells having a plurality of layers frictionally connected to each other, at least one receiver and, optionally, a transmitter. The receiver receives acoustic plate waves and/or acoustic torsion waves and transmits a corresponding signal to an evaluating unit that evaluates parameters characteristic for an actual state of the battery cell, and compares them to at least one previously defined threshold. Exceeding or falling short of the threshold is evaluated as identification of battery cells having a critical change to the physical properties thereof. A transmitter of the diagnostic device is suitable for exciting the acoustic plate waves or torsion waves in the battery cell having a propagation direction along the layers.

### FIELD OF THE INVENTION

The invention relates to a diagnostic device for critical changes, particularly pressure changes, gas formation and temperature changes, in batteries having multi-layered structures, to a battery system having such a diagnostic device and to a method for diagnosing critical changes of such batteries by means of the diagnostic device.

### BACKGROUND OF THE INVENTION

The use of electric or electronic devices, in particular portable devices, is often dependent on electrochemical cells for power supply, so-called “battery cells” or “batteries.” Batteries can be used in electronic devices such as telecommunication devices (for example, cellphones, tablets, computers), transport means (for example, cars, airplanes, boats), but also in non-portable devices such as backup batteries for central power supplies.

Due to outside operating conditions of battery cells, such as excessively high current intensities, excessively high mechanical forces on the cell housing or on the contacts, overcharging or deep discharging, or excessively high or excessively low cell voltage, or excessively high or an excessively low cell temperatures, the electrochemical equilibrium in the cell shifts, and the cell can reach a critical state. In addition, the cell can also reach critical states due to aging-caused degeneration mechanisms. The critical state can lead to capacitance losses, to increases of the internal resistance, or to exothermal processes. These in turn can represent hazards not only for the devices but also for persons. More recent examples are the battery problems in the Galaxy Note 7 of Samsung or the burning battery pack in the Boeing 787 Dreamliner. Early detection is therefore desirable, in order to be able to take countermeasures, before these batteries represent a hazard.

It is known to measure, by measuring electrical variables such as current and voltage, the state of charge (SOC) and the internal resistance of a battery and to evaluate on the basis of this the aging state and the state of health (SOH). In addition, invasive methods are used to gain insights on the chemical composition and the construction of the cell. The associated interventions cause the battery to age prematurely or lead to direct destruction. Noninvasive methods have therefore been developed, which determine the state of charge and possibly the state of the battery by transmitting and receiving the acoustic volume waves.

The main disadvantage of the above-mentioned methods is that the measured volume waves have a low sensitivity to material changes and impurities, which are indicative of a critical state. This is due to the small size of a wave packet compared to the battery cell and the associated small interaction surface. Thus, a large impurity (physical change or gas amount) is necessary in order to obtain a significant change of the measurement signal, that is to say impurities. Thus, this method is not sensitive and error prone with respect to small impurities which can, however, be critical for the useful life and/or the state of the battery cell.

Therefore, it would be desirable to have available a diagnostic possibility which does not damage the battery cell and which does not have the disadvantages of the prior art.

### SUMMARY OF THE INVENTION

Therefore, one aim of the invention is to have available a diagnostic possibility which does not damage the battery cell and which overcomes the disadvantages of the prior art.

This aim is achieved by a diagnostic device for determining critical changes to physical properties relative to a nominal state in battery cells having a structure comprising a plurality of layers, wherein the layers are force-fitted to each other, having at least one receiver and, optionally, additionally, a transmitter for arrangement on the housing and/or cell contact of the battery cell, wherein the receiver is suitable for receiving acoustic plate waves and/or acoustic torsion waves and for transmitting a corresponding signal to an evaluating unit, which is provided to evaluate one or more parameters which are characteristic for an actual state of the battery cell, and for comparing them to at least one previously defined threshold, wherein exceeding or falling short of the threshold is considered as being identification of battery cells having a critical change to the physical properties thereof, wherein, in the case of the diagnostic device having a transmitter, the transmitter is suitable for exciting the acoustic plate waves and/or the acoustic torsion waves in the battery cell having a propagation direction along the layers.

The term “critical change to physical properties” is understood to mean that reaching a critical state, in which, for example, the formation of gases and the pressure changes in the battery cells can have the effect of leading to a defect or destruction of the battery. Usually, these effects result from the decomposition of the electrolytes, in part to gaseous components and reaction products in the battery cell, which cannot be detected thermally or electrically in the early phase. These gaseous components and reaction products are, on the one hand, highly flammable, and, on the other hand, they lead to a pressure increase within the battery cell, which in turn leads to mechanical stresses in the cell housing, since the battery cell is enclosed by a gas- tight cell housing, from which the gases cannot escape. Depending on the housing type and tensions of the battery cell, this can lead, in the battery system, to a strong or slight deformation of the cell housing, which is generally referred to as “swelling.” Moreover, aging mechanisms can be the cause of electrolyte decompositions which lead to critical changes. In the case of internal short circuits as well, which result, on the one hand, from mechanical effects or from metallic lithium dendrites, the battery cell can critically change.

Battery cells are understood to mean electrochemical cells which can store electrical energy and make it available. Batteries in the sense of this invention are batteries having a structure comprising a plurality of layers, wherein the layers are force-fitted to each other. They include commercial batteries such as, for example, lithium ion batteries, nickel metal hydride accumulators (NiMH) and electrochemical capacitors.

Transmitters or receivers are understood to mean any suitable transmitters and receivers for transmitting and receiving any type of acoustic plate waves and acoustic torsion waves. They include, for example, wedge converters (angle probe heads in the ultrasound measuring technology), interdigital converters with piezoelectric plates as well as certain laser excitations, etc.

“Acoustic waves” are understood to mean a propagation of local pressure disturbances and particle shifts in an elastic medium. In contrast to acoustic volume waves, which require an unlimited propagation medium, acoustic plate waves are influenced by the boundary surfaces of the “plates.” The layers within the battery cells themselves can be considered boundary surfaces. Acoustic plate waves include, among others, Lamb waves, horizontally polarized shear waves (HPSW) and vertically polarized shear waves (VPSW). For the differentiation between the different wave types, coordinates for the different wave components are defined. Coordinate x stands for the main propagation direction of the irradiated wave along the layers. The plane x-y denotes the plate plane, that is to say the plane of the layers in the battery cell. The propagation direction is perpendicular to the x-y plane; for example, Lamb waves describe waves that have two propagation components, one of which extends in the propagation direction x (longitudinal) and the other perpendicularly thereto along the propagation component z (transversal). Here, the propagation direction of the wave is considered to be in the plane of the x-y plane. HPSW travel horizontally in the plate plane (x-y plane) perpendicularly to the propagation direction along the propagation component y. These waves can be described as transversal waves. VPSW also travel perpendicularly to the propagation direction along the component z which extends orthogonally to the plate plane (x-y plane). They extend practically out of the plate plane.

The difference with respect to volume waves consists of the boundary surface conditions. While the “volume wave” wave type is not limited by the boundary surfaces and deploy freely in the medium, the “plate wave” wave type is limited by at least two boundary surfaces (of the two surfaces of the “plate”). As a result, in the case of plate waves, many more different and differentiated propagation possibilities exist, also referred to as wave modes, than in the case of volume waves, which is an enormous advantage in the detection of impurities in the battery cells. “Acoustic plate waves” and “plate waves” are here considered synonyms.

Torsion waves, also referred to as cylinder waves, are understood to mean waves which start from a straight line in a homogeneous and isotropic medium. They propagate similarly to Lamb waves, except that the cylinder surfaces are to be considered the boundary surfaces, and not the plate surfaces. In addition, cylinder waves can also propagate in hollow cylinders or tubes. Torsion waves equivalent to the HPSW and VPSW are also possible, which have a component perpendicular to the propagation direction. As a result, torsion waves, just like plate waves, have a larger variety of propagation directions than volume waves and are therefore better suited for detecting impurities in the battery cell. “Acoustic torsion waves” and “torsion waves” or “cylinder waves,” are here considered to be synonyms.

In contrast to the prior art, the present invention is substantially based on guided ultrasound waves (the above-mentioned plate and torsion waves). These waves propagate within the individual layers in the battery cell; in other words, the waves are guided by the individual layers of the battery cell. It is only in this way that it is possible to couple in the waves at a first site on the battery cell and to receive them at a second site of the battery cell in such a manner that the second site does not have to be located outside of the acoustic axis of the sensors. When the guided waves propagate along the individual layers which function as waveguides, they interact with the respective adjoining layers (adjacent layers of the battery cell). This interaction results in changes to the original propagation parameters which can then be acquired and evaluated. In the prior art, exclusively waves for the detection of the battery states are impressed only into the volume of the battery cell, so that only volume waves can propagate in the electrochemical storage device. Accordingly, the present invention provides a much more precise and direction-independent type of measurement of states and changes in battery cells.

An evaluating unit is understood to mean, for example, a processor, a chip, a server, any unit which is capable of implementing and executing a computer program, in order to evaluate the measured parameters.

Parameters are understood to mean everything that is characteristic for the measured signal. This includes, among other properties, the travel time and the amplitude of the signal. From these parameters in turn, the frequency spectrum, the integral of the amplitude square or of the amplitude absolute value, the short time Fourier transform (STFT), the wavelet transform (WT) and the energy of the signal.

A wedge converter is understood to mean a common monomodal converter configuration, with which the angle of incidence can be controlled. This configuration is frequently used in the ultrasound technology in the form of angle probe heads.

These converters consist of a wedge which defines a wedge angle a between the upper wedge surface and the surface of the object to be measured, on which the wedge is applied, and to the top side of which a piezoceramic is coupled. The ceramic is implemented as a plate or a disk. The piezoceramic excites a wave with a desired wavelength in the wedge. The wedge ensures that this wave strikes the plate surface at a certain angle and induces a harmonic, spatially delimited strain distribution there. By the adjustment of the form of the strain distribution to the wavelength, for example, of a Lamb wave, this wave type can be selectively excited and received. The adjustment of the wavelengths here occurs via the wedge angle a which can be calculated using the law of refraction.

The wedge converter thus has the advantage that different wave types can be controlled by varying the wedge angle. In addition, the converter transmits only one unidirectional propagation field of Lamb waves, whereby reflections in the plate structure can be minimized.

Interdigital converters are understood to mean mode-selective converters, the operating principle of which is based on so-called acoustic surface wave filters which transmit and receive Rayleigh waves and which are used in telecommunication for frequency filtering. The interdigital converter consists of two comb-like interlocking electrodes with different polarity. In the present invention, the comb-like structure is arranged on electrodes parallel to the surface of the battery cell. Lamb waves propagate with relatively large wavelengths, so that the electrodes have to be designed to be relatively long so that the electric field is generated in thickness direction. As material for the interdigital converters, piezoceramic plates as well as PVDF films are used.

When applied flat on the plate structure, the structuring electrodes have the effect that the converters induce a spatially varying, finite strain distribution on the plate surface. When the spacings of the electrodes are adjusted to the wavelength of a mode and the converters are operated at a frequency, it is possible to selectively excite or receive a certain mode. This ensures the precise control of the desired wave type (Lamb, HPSW, VPSW).

The diagnostic device according to the invention makes available a diagnostic possibility, with which the battery is not damaged during the diagnosis and which overcomes the disadvantages of the prior art.

When using batteries, a limited storage space for accommodating the battery in the housing constitutes an impediment for the attachment of external sensors. Therefore, it is desirable that the diagnostic device takes up as little space as possible. To save not only space but also material, in an embodiment, the transmitter is also the receiver. In this case, the wave covers a maximum distance from the transmitter back to the receiver, which means that the wave packets have a large interaction surface and which leads to a significant change of the measurement signal.

In an embodiment, the transmitter is an interdigital converter with comb-like interlocking electrodes with spacings between the electrodes, which are equal to a predetermined wavelength. The flat form of interdigital converters makes it possible to attach them to the housing of the battery cells in a highly space-saving manner.

In an embodiment, the transmitter is a wedge converter, wherein the angle of incidence of the transmitter is selected so that the incident wave is refracted at a 90° angle in wave propagation direction and thus transmits into the layers of the battery cell. In general, two critical angles exist, one for longitudinal waves and one for transversal waves. Other angles are also possible, since the waves in the layers of the battery cell are excited less effectively. The same also applies to wedge converters as receivers. These wedge converters, also referred to as angle probe heads, are conventionally used in the ultrasound measuring technology and have the advantage of variable designs and sizes. In addition, the wedge converters which are determined by a fixed wavelength can be adjusted very easily to the desired angle. Thus, using only one transmitter, the excitation of all the acoustic wave types is possible. The critical angle can be determined by Snell's law.

In an additional embodiment, the transmitter is an ultrasound sensor. Ultrasound sensors are known to be suitable for exciting and receiving elastic waves. They detect the desired spacing by means of ultrasound waves. The head of the sensor transmits an ultrasound wave, which is reflected back by all the layers of the battery cell (including the housing, depending on where the sensor is located). The time between transmission and reception of the ultrasound wave is measured. In contrast to an optical sensor which has a transmitter and a separate receiver, the ultrasound sensor can be the same ultrasound element for transmitting and receiving. In an ultrasound sensor of the reflection type, the ultrasound waves are alternately transmitted by an individual oscillator and again received by it. Thereby, the sensor head can be kept very small. Other transmitters which can be used instead of ultrasound sensors are piezoelectric ceramics and piezoelectric films made of PVDF.

In an additional embodiment, the ultrasound sensor excites the plate waves and/or torsion waves by means of at least one piezoelectric element and/or of at least one electromagnetic acoustic converter and/or of one or more laser excitations and/or of at least one interdigital converter. Here, piezoelectric elements which are, for example, piezoelectric ceramics or films have very good electromechanical couplings. Together with electromagnetic acoustic converters, they generate a good ratio between electrical voltage input and mechanical voltage output and vice versa.

In an additional embodiment, the sensor is a thickness-mode or shear-mode oscillator to be force-fitted to the battery cell. Acoustic plate waves and torsion waves can be excited by thickness-mode or shear-mode oscillators which are frictionally attached directly to the battery cell. The propagation of the waves in longitudinal direction of the individual battery layers occurs by the transverse contraction which is described by the transverse contraction number (Poisson number).

A laser excitation and electromagnetic acoustic converters enable a contact-free excitation, which is advantageous in some situations. Interdigital converters have the advantage of being capable of very flat application on the housing of the battery cell, whereby the volume of a battery cell with transmitter differs little from the volume of just a battery cell without sensor.

The plate waves excited by the different embodiments are Lamb waves, horizontally polarized shear waves or vertically polarized shear waves. Plate waves cannot be confused with surface waves or volume waves. While the volume wave type is not limited by any boundary surfaces and can deploy freely in the medium and the surface wave type is restricted by only one boundary surface, the plate wave type is limited by at least two boundary surfaces (of the two surfaces of the plate). Thereby, in the case of plate waves, many more different and differentiated propagation possibilities are generated than in the case of volume waves, which is an enormous advantage in the detection of impurities in the battery cells. “Acoustic plate waves” and “plate waves” are here considered to be synonyms. The characterizing polarization directions of the Lamb waves, HPSW and VPSW enable the detection of different impurities in the material. By the selection of one of these wave types as main excitation, a certain type of impurities can be measured in a targeted and precise manner. This selection in turn can lead to a targeted and precise diagnosis of a defect of the battery cell.

In addition, the excited plate waves can also consist of any combination of

Lamb waves, horizontally polarized shear waves and vertically polarized shear waves. Different plate waves characterize different changes in the battery cell. Therefore, using a combination of different plate waves, a more precise evaluation of the overall state of the battery can be determined, since different physical effects can be identified in one measurement.

In an additional embodiment, the excitation of the plate waves and/or torsion waves occurs continuously or in the form of pulses. In a continuous excitation, it is possible to detect changes to physical properties in real time (immediately). However, this excitation has the disadvantage that a continuous energy consumption is necessary. In a pulse-form excitation, the transmission is a point transmission, which makes the diagnostic device more energy efficient. Here, the pulse-form excitation as well can meet the required real-time criteria in the time regions in question.

In an additional embodiment, the transmitter is configured to excite the plate waves and/or torsion waves with a frequency of 100 kHz to 10 MHz in the battery cell. The low- frequency region is defined to be between approximately 100 kHz and 500 kHz. Low-frequency waves are damped less by the individual layers and thus have a high amplitude during the measurement. However, due to the reflection on the boundary surfaces (layers), these low- frequency waves have a weaker interaction with possible impurities. This in turn leads to a lower sensitivity or defects in the material, in contrast to high-frequency waves. High-frequency waves start at one MHz. They are damped more, but they have a much better sensitivity with regard to the detection of defects in the material. In particular, a combination of the two waves can be used in a targeted manner in order to achieve more precise diagnoses.

In detail, due to the dispersion properties of the material, the low-frequency waves interact in another manner with possible changes in the battery cell compared to high-frequency waves. In general, at different frequencies, this leads to a different sensitivity with regard to different material changes. At low frequency, depending on the change, this can accordingly also lead to a higher sensitivity. This also applies for high frequencies. For example, high-frequency waves are influenced or damped more strongly by spatial defects than low-frequency waves and thus they have a higher sensitivity with respect to local changes in the battery cell. Therefore, it is advantageous to use both high-frequency waves and also low-frequency waves in order to be able to detect different changes or defects in the battery cell more precisely and as a result obtain an even more precise diagnosis result.

In an additional embodiment, the excitation consists of a frequency spectrum with different frequencies. This enables a more precise examination of the battery cell, since different frequencies can detect different defects.

Furthermore, in order to solve the technical problem, a battery system with diagnostic function is made available, which comprises a battery cell having a structure consisting of multiple layers, wherein the layers are force-fitted to each other, and a diagnostic device according to claim 1 for determining critical changes to physical properties relative to a nominal state in battery cells having at least one receiver and, optionally, additionally, a transmitter for arrangement on the housing and/or cell contact of the battery cell, wherein the receiver is suitable for receiving acoustic plate waves and/or acoustic torsion waves and for transmitting a corresponding signal to an evaluating unit, which is provided in order to evaluate one or more parameters which are characteristic for an actual state of the battery cell, and for comparing them to at least one previously defined threshold, wherein exceeding or falling short of the critical threshold is considered as being identification of battery cells having a critical change to the physical properties thereof, wherein, in the case of the diagnostic device having a transmitter, the transmitter is suitable for exciting the acoustic plate waves and/or the acoustic torsion waves in the battery cell having a propagation direction along the layers.

The use of the battery system yields numerous advantages. For example, the battery cells can be monitored from the time of their production on for their aging state and state of health. The same also applies for battery modules and battery packs. During the monitoring, it is possible to detect the electric and thermal parameters (such as, for example, cell temperature). By means of algorithms, the state of the battery cells can be determined from the measured parameters. Exceeding or falling short of certain thresholds such as, for example, the minimum and maximum signal voltage, can result in early detection of a critical state. Subsequently, suitable active as well as passive counter-measures can be taken, in order to minimize hazards and losses.

In an embodiment of the battery system, at least one of the transmitters and at least one of the receivers are arranged on the same battery cell side. “Same” battery cell side is understood to mean when the shortest distance between (at least) two sites, which were selected for the transmitting and the receiving, extends/contains/is tangential to only one layer. By means of this arrangement, an elevated amplitude is measured, since the wave travels primarily along the surface and has to pass through fewer interactions. When the physical properties of the battery cells are changed relative to the target cell, as, for example, in the case of gas formation in the battery cell, the amplitude of the measurement signal increases, since the impurity, for example, a gas bubble, reflects the wave back again. Exceeding a threshold is accordingly an indicator for a physical change, for example, in the form of a gas bubble, in the battery cell.

In an additional embodiment of the battery system, at least one of the transmitters and at least one of the receivers are arranged on different battery cell sides. “Different” battery cell system is understood to mean when the shortest distance between (at least) two sites, which were selected for the transmitting and receiving, extends through several layers. By the frictional connection connecting the layers in the battery cell directly to each other (pressing on), a good propagation of the wave through the layers is ensured. The good transmission from one battery cell side to the other side is reduced by an impurity in the material. Falling short of a threshold accordingly can be an indicator of a change in the battery cell. Here the transmitter and receiver are preferably not arranged facing, but offset in propagation direction of the wave on the battery cell. In the case of gas formation, the receiver, which is arranged offset relative to the transmitter (for example, on the other side), receives a weakened signal, since energy is reflected by the enclosed gas in the direction of the transmitter.

In an embodiment of the battery system, at least one of the transmitters and at least one of the receivers are arranged on the same cell contact or on different cell contacts. The cell contact is the “same” cell contact, when it is the same terminal of a battery cell. Cell contacts are “different” cell contacts, when the sensors are attached on different terminals. Often, due to the environment for the embedding of the battery, it is difficult to attach sensors to the battery cell sides. In order to solve this problem, the sensors are attached on the cell contacts of the battery. By means of the transmission direction of the wave, the measured signal can also give information on the adhesion of the coating of the electrodes in the interior of the battery cell.

When all of the transmitters as well as all of the receivers are attached on the same cell contact, exceeding a threshold is an indicator that changes such as gas formation, for example, occur within the battery cell. When the transmitters and receivers are attached on different cell contacts, a falling short of a threshold is considered as being a change to physical properties.

In an embodiment of the battery system, at least one of the transmitters is attached on a battery cell side, and at least one of the receivers is attached on a cell contact and vice versa. The advantage consists in that, in many situations, only this configuration is allowed. In this arrangement, a falling short of a threshold can be considered as being an indicator for the change to physical properties in the battery cell.

The invention moreover relates to a method for diagnosing a change to physical properties relative to a nominal state of battery cells having a structure comprising multiple layers, wherein the layers are force-fitted to each other, comprising

an arranging of at least one receiver on the housing and/or cell contact of the battery cell,

a receiving of acoustic plate waves and/or acoustic torsion waves by the receiver,

a transmitting of a corresponding signal by the receiver to an evaluating unit,

an evaluating of one or more parameters which are characteristic for an actual state of the battery cell, by the evaluating unit,

a comparing of the evaluated parameters with at least one previously defined threshold,

an assessing of an exceeding or falling short of the threshold as identification of battery cells having a change to the physical properties.

The method, in addition, provides the possibility of deriving material properties of the battery cell. They include: the average pressure within the cell, the modulus of elasticity, the shearing modulus, the density, the layer height, the phase transitions from solid to liquid, liquid to solid, solid to gaseous, liquid to gaseous, and gaseous to liquid. In addition, changes in the mechanical structure can be detected, such as the delamination between different layers of the battery, such as active material and conductor and/or the delamination of the contact tabs (cell contacts) and/or the delamination of individual layers of the contact tab.

In addition to the receiver, an embodiment of the method provides at least one transmitter for exciting acoustic plate waves and/or torsion waves in the battery cell having a propagation direction along the layers, which is arranged on the housing and/or cell contact of the battery cell. Thereby, an active transmission of the wave to be measured is possible.

Here, the transmitters and receivers are preferably not facing, but instead offset in propagation direction of the wave on the battery cell.

An embodiment of the method provides that the evaluating comprises the parameters amplitude and travel time of the signal. These received signals can be evaluated with different methods. Here, it is possible to use both analog and also digital filters. From the measurement signals, it is possible to derive, inter alia, the energy, the frequency, the integral of the amplitude square or of the amplitude absolute value, the frequency spectrum of the entire signal by Fourier transform or fast Fourier transform, the frequency spectrum in individual regions by short time Fourier transform, the pulse spectrum in the individual regions of the signal by wavelet transform. The mathematical methods for the different transforms/procedures can be a combination of different window functions, for example, rectangular window, Hann window, Hamming window, Gaussian window, Blackman window, Blackman-Harris window, Blackman- Nuttal window, flat top window, Bartlett window, Bartlett-Hann window, cosine window, Tukey window, Lanczos window, Kaiser window, Gaussian window, etc.

The measurement results obtained can be stored, and changing measurement results over time can be compared to one another. They can be evaluated using stochastic methods, in order to assess the change to the physical properties of a battery cell over time. An embodiment of the method consists in generating a prognosis of the physical changes, preferably temperature changes, in the battery cell in the future by evaluating the parameters over time. By the evaluation of the measurement results over time, in particular critical results are to be prognosticated early, in that short changes to the physical properties are identified and evaluated.

In an additional embodiment of the method, the state of charge of the battery cell is determined, in that the ultrasound signals are correlated with the electrical measurement signals.

### BRIEF DESCRIPTION OF THE FIGURES

The brief description and other aspects of the invention are shown in detail in the figures, as follows:

FIG. 1: Battery system with diagnostic function, comprising a battery cell having a structure comprising multiple layers and the diagnostic device according to the invention.

FIG. 2: Diagnostic device for determining critical changes to physical properties relative to a nominal state in battery cells.

FIG. 3: Arrangement of wedge converter for transmitting and/or receiving acoustic plate and/or torsion waves on the battery.

FIG. 4: Interdigital converter with comb-like electrodes.

FIG. 5: Method for diagnosing a change to physical properties relative to a nominal state of battery cells.

FIG. 6: Course of a measurement signal measured using the diagnostic device according to the invention and applying the method according to the invention.

### DETAILED DESCRIPTION OF THE EMBODIMENT EXAMPLES

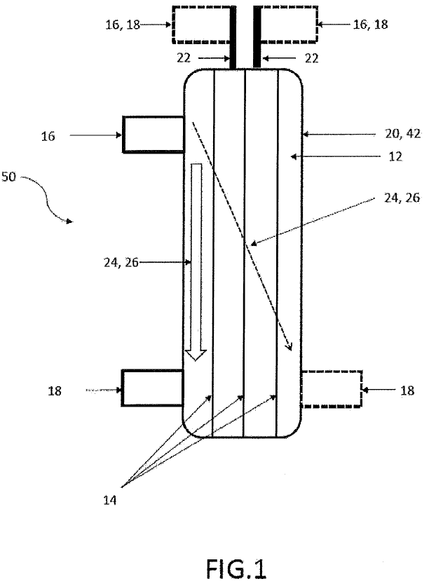

FIG. 1 shows a battery system 50 with diagnostic function, comprising a battery cell 12 having a structure comprising a plurality of layers 14, wherein the layers 14 are force-fitted to each other, and a diagnostic device 10 according to the invention for determining critical changes to physical properties relative to a nominal state in battery cells 12. The battery system 50 has at least one receiver 18 and, optionally, additionally, a transmitter 16 for arrangement on the housing 20 and/or cell contact 22 of the battery cell 12. The receiver 18 is suitable for receiving acoustic plate waves 24 and/or acoustic torsion waves 26 and for transmitting a corresponding signal 28 to an evaluating unit 30. The evaluating unit 30 is provided in order to evaluate one or more parameters 32, which are characteristic for an actual state of the battery cell 12, and for comparing them to at least one previously defined threshold 34. Here, exceeding or falling short of the threshold 34 is considered as being identification of battery cells having a critical change to the physical properties thereof. In the case of a battery system 50 with the transmitter 16, the transmitter 16 is suitable for exciting the acoustic plate waves 24 and/or the acoustic torsion waves 26 in the battery cell 12 having a propagation direction along the layers 14. Here, the transmitter 16 can at the same time also be the receiver 18. Moreover, in the case of a battery system with transmitter 16, at least one of the transmitters and at least one of the receivers can be arranged on the same battery cell side 42, 20. In addition, at least one of the transmitters and at least one of the receivers can be arranged on different battery cell sides 42, 20. Thus, the propagation parameters of the plate wave and/or torsion waves can also be measured by the individual cell layers. In an embodiment, at least one of the transmitters and at least one of the receivers can be arranged on the same cell contact 22 or on different cell contacts 22. In an additional embodiment, at least one of the senders can be arranged on a battery cell side 42, 20, and at least one of the receivers can be arranged on a cell contact 22 and vice versa.

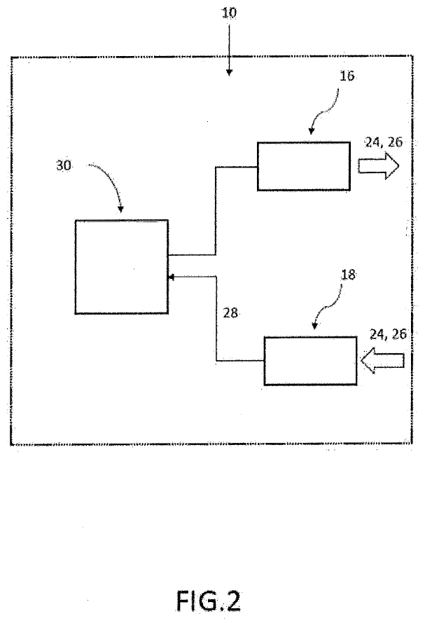

FIG. 2 shows a diagnostic device 10 for determining critical changes to physical properties relative to a nominal state in battery cells 12 having a structure comprising a plurality of layers 14, wherein the layers 14 are force-fitted to each other. The diagnostic device 10 has at least one receiver 18 and, optionally, additionally, a transmitter 16 for arrangement on the housing 20 and/or cell contact 22 of the battery cell 12. The receiver 18 is suitable for receiving acoustic plate waves 24 and/or acoustic torsion waves 26 and for transmitting a corresponding signal 28 to an evaluating unit 30. The evaluating unit 30 is provided in order to evaluate one or more parameters 32, which are characteristic for an actual state of the battery cell 12, and for comparing them to at least one previously defined threshold 34. Here, exceeding or falling short of the threshold 34 is considered as being identification of battery cells having a critical change to the physical properties thereof. In the case of a diagnostic device 10 with transmitter 16, the transmitter 16 is suitable for exciting the acoustic plate waves 24 and/or the acoustic torsion waves 26 in the battery cell 12 having a propagation direction along the layers 14. Here, the transmitter 16 can at the same time be also the receiver 18. The transmitter 16, 18 can be an interdigital converter 36 with comb-like interlocking electrodes 38 with spacings between the electrodes 38, which are equal to a predetermined wavelength. In an embodiment, the transmitter 16, 18 is a wedge converter 40, wherein the transmitter 16, 18, 40 is oriented so that it can transmit at a critical angle into the layers 14 of the battery cell 12. The transmitter 16, 18, 36, 40 can be an ultrasound sensor. The ultrasound sensor can excite the plate waves 24 and/or torsion waves 26 by means of at least one piezoelectric element and/or of at least one electromagnetic acoustic converter and/or of one or more laser excitations and/or of at least one interdigital converter. The excited plate waves 24 can be Lamb waves or horizontally polarized shear waves or vertically polarized shear waves or any combination of Lamb waves, horizontally polarized shear waves and vertically polarized shear waves. The excitation of the plate waves 24 and/or torsion waves 26 can occur continuously or in the form of pulses. The transmitter 16, 18, 36, 40 can moreover be designed so that plate waves 24 and/or torsion waves 26 are excited with a frequency of 100 kHz to 10 MHz in the battery cell. Moreover, an excitation can consist of a frequency spectrum with different frequencies.

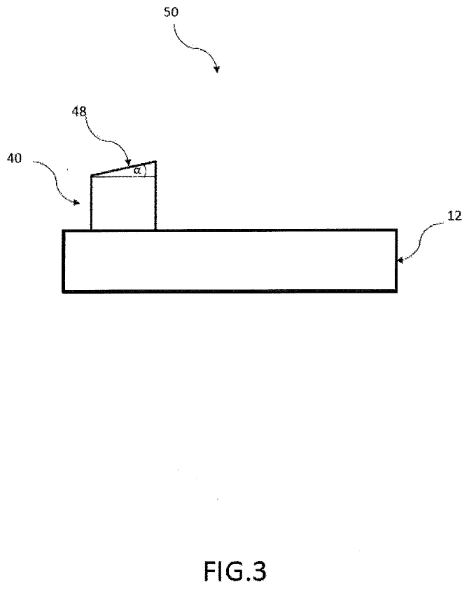

FIG. 3 shows a battery system 50 with a wedge converter 40 for transmitting and/or receiving acoustic plate waves 24 and/or torsion waves 26, wherein the transmitter wedge converter 40 can be oriented so that it transmits at a critical angle into the layers 14 of the battery cell 12. The wedge converter 40 consists of a wedge which defines a wedge angle a between the upper wedge surface 48 and the surface of the object to be measured, on which the wedge is applied and on the upper side of which a piezoceramic is coupled. The ceramic is implemented as a plate or disk. The piezoceramic excites a wave with a desired wavelength in the wedge. The wedge ensures that this wave strikes the plate surface at a certain angle and induces a harmonic, spatially limited strain distribution there. By the adjustment of the form of the strain distribution to the wavelength, for example, of a Lamb wave, this wave type can be selectively excited and received. The adjustment of the wavelengths here occurs via the wedge angle a, which can be calculated by means of the law of refraction. For the excitation of Lamb waves, thickness-mode oscillators can be used, and for the excitation of HPSW and VPSW, shear-mode oscillators can be used.

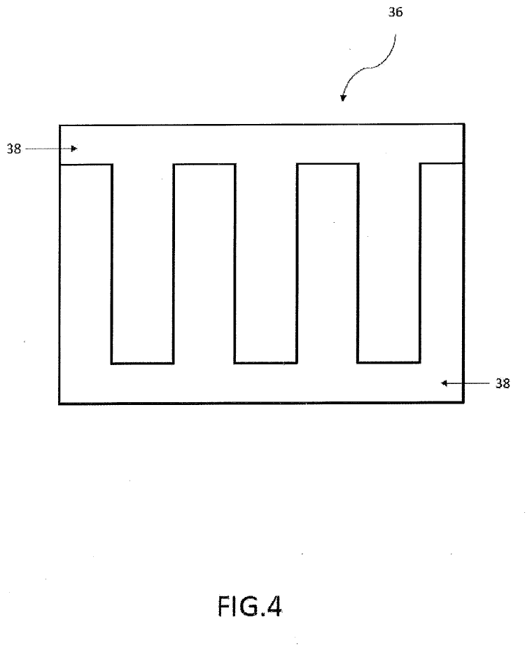

FIG. 4 shows an interdigital converter 36 as transmitter 16, 18, 36, 40 with comb-like, interlocking electrodes 38 with different polarity, which can have spacings between the electrodes 38, which are equal to a predetermined wavelength. In the present invention, the comb-like structure is arranged on electrodes 38 parallel to the surface of the battery cell 12. As material for the interdigital converters 36, both piezoceramic plates and also PVDF films are used. When applied flat to the plate structure, the structured electrodes 38 have the effect that the converters 36 induce a spatially varying finite strain distribution on the plate surface. When the spacings of the electrodes 38 are adjusted to the wavelength of a mode and the converters 36 are operated at a frequency, it is possible to selectively excite or receive a certain mode. This ensures the precise control of the desired wave type (Lamb, HPSW, VPSW). However, a thickness-mode or shear-mode oscillator (piezoelectric plate) which is frictionally attached to the battery cell 12 can also be used. The excitation in propagation direction along the battery electrode occurs due to the transverse contraction (Poisson number).

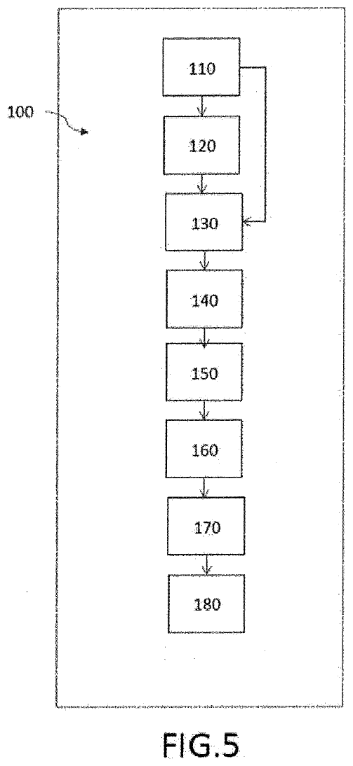

FIG. 5 shows a method 100 for diagnosing a change to physical properties relative to a nominal state of battery cells 12 having a structure comprising several layers 14, wherein the layers 14 are force-fitted to each other. The method comprises an arranging 110 of at least one receiver on the housing and/or cell contact of the battery cell, a receiving 130 of acoustic plate waves and/or acoustic torsion waves by the receiver, a transmitting 140 of a corresponding signal by the receiver to an evaluating unit, an evaluating 150 of one or more parameters which are characteristic for an actual state of the battery cell by the evaluating unit, a comparing 160 of the evaluated parameters to at least one previously defined threshold, and an assessing 170 of an exceeding or falling below the threshold as indication of battery cells having a change to the physical properties. In addition, the method 100 can contain at least one transmitter for the exciting 120 of acoustic plate waves and/or torsion waves in the battery cell having a propagation direction along the layers, which is arranged on the housing and/or cell contact of the battery cell. The evaluating 150 of the parameters 32 can have an amplitude 44, 32 and a travel time 46, 32 of a signal 28. Moreover, a prognosis 180 of the physical changes to the battery cell in the future can be generated by evaluating the parameters 32 over time.

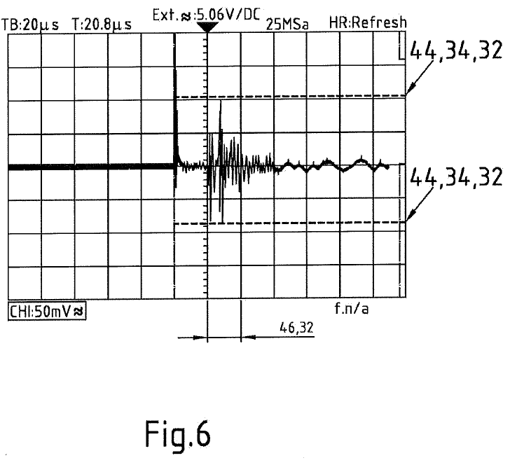

FIG. 6 shows the course of a measurement signal measured using the diagnostic device 10 according to the invention and applying the method 100 according to the invention. The parameters of amplitude (both positive and also negative) 44, 32 can here be defined as threshold 34. The travel time 46, 32 is referred to as the time which the sent in signal needs to reach the receiver.

The embodiment examples shown here only represent examples of the present invention and should therefore not be understood to be limiting. Alternative embodiments taken into consideration by the person skilled in the art are, likewise, covered by the scope of protection of the present invention.

### LIST OF REFERENCE NUMERALS

10. Diagnostic device according to the invention
12 Battery cell
14 Layers (of the battery cell)
16 Transmitter
18 Receiver
20 Housing
24 Acoustic plate wave
26 Acoustic torsion wave
28 Signal
30 Evaluating unit
32 Parameter
34 Threshold
36 Interdigital converter
38 Comb-like interlocking electrodes
40 Wedge converter
42 Battery cell side
44 Amplitude
46 Travel time
48 Upper wedge surface
50 Battery system
100 Method according to the invention
110 Arranging of receivers
120 Exciting of acoustic plate and/or torsion waves
130 Receiving of acoustic plate waves and/or acoustic torsion waves
140 Transmitting of a corresponding signal
150 Evaluating of one or more parameters
160 Comparing the evaluated parameters
170 Assessing an exceeding or a falling short of the threshold
180 Generating a prognosis of physical changes of the batter cell
a Wedge angle
   . (Currently amended) A diagnostic device for determining critical changes to physical properties relative to a nominal state in battery cells having a structure comprising:
   a plurality of layers, wherein the layers are force-fitted to each other;
   at least one receiver,
   suitable for receiving acoustic plate waves and/or acoustic torsion waves, and for transmitting a corresponding signal to an evaluating unit, said evaluating unit being provided to evaluate one or more parameters which are characteristic for an actual state of the battery cell, and for comparing the one or more parameters to at least one previously defined threshold, wherein exceeding or falling short of the threshold is considered as being identification of battery cells having a critical change to the physical properties thereof.

2. The diagnostic device according to claim 22, wherein the transmitter is also a receiver.

3. The diagnostic device according to claim 22, wherein the transmitter is an interdigital converter with comb-like interlocking electrodes with spacings between the electrodes which are equal to a predetermined wavelength.

4. The diagnostic device according to claim 22, wherein the transmitter is a wedge converter, and wherein the transmitter is oriented so as to transmit at a critical angle into the layers of the battery cell.

5. The diagnostic device according to claim 22, wherein the transmitter is a thickness-mode or shear-mode oscillator that is frictionally attached to the battery cell.

6. The diagnostic device according to claim 22, wherein the transmitter is an ultrasound sensor.

7. The diagnostic device according to claim 6, wherein the ultrasound sensor excites the acoustic plate waves and/or acoustic torsion waves by means of at least one piezoelectric element and/or at least one electromagnetic acoustic converter and/or one or more laser excitations and/or at least one interdigital converter.

8. The diagnostic device according to claim 1, wherein the acoustic plate waves are either Lamb waves or horizontally polarized shear waves or vertically polarized shear waves or any combination of Lamb waves, horizontally polarized shear waves and/or vertically polarized shear waves.

9. (canceled)

10. The diagnostic device according to claim 22, wherein the excitation of the acoustic plate waves and/or acoustic torsion waves occurs continuously or in the form of pulses or wherein the excitation comprises a frequency spectrum with different frequencies.

11. The diagnostic device according to claim 22, wherein the transmitter is configured to excite the acoustic plate waves, and/or acoustic torsion waves with a frequency of 100 kHz to 10 MHz in the battery cell.

12. (canceled)

13. A battery system with diagnostic function, comprising a battery cell having a structure comprising a plurality of layers, wherein the layers are force-fitted to each other, and a diagnostic device for determining critical changes to physical properties relative to a nominal state in battery cells, wherein the diagnostic device has at least one receiver is suitable for receiving acoustic plate waves and/or acoustic torsion waves and for transmitting a corresponding signal to an evaluating unit, which is provided to evaluate one or more parameters which are characteristic for an actual state of the battery cell, and for comparing the one or more parameters to at least one previously defined threshold, wherein exceeding or falling short of the threshold is considered as being identification of battery cells having a critical change to the physical properties thereof.

14. The battery system according to claim 23, wherein at least one of the at least one transmitter and at least one of the at least one receiver are arranged on the same battery cell side or at least one of the at least one transmitter and at least one of the at least one receiver are arranged on different battery cell sides.

15. (canceled)

16. The battery system according to claim 23, wherein at least one of the at least one transmitter and at least one of the at least one receiver are arranged on the same cell contact or on different cell contacts.

17. The battery system according to claim 23, wherein at least one of the at least one transmitter is attached on one battery cell side and at least one of the of the at least one receiver is attached on a cell contact and vice versa.

18. A method (100) for diagnosing changes to physical properties relative to a nominal state of battery cells having a structure comprising a plurality of layers, wherein the layers are force-fitted to each other, said method comprising:
arranging at least one receiver on a housing and/or a cell contact of a battery cell;
receiving acoustic plate waves and/or acoustic torsion waves with the at least one receiver;
transmitting a corresponding signal by the at least one receiver to an evaluating unit;
evaluating one or more parameters which are characteristic for an actual state of the battery cell, by the evaluating unit;
comparing the evaluated parameters with at least one previously defined threshold; and
assessing an exceeding or a falling short of the threshold as identification of battery cells having a change to the physical properties.

19. The method according to claim 18 further comprising arranging, on the housing and/or cell contact of the battery cell, at least one transmitter for exciting acoustic plate waves and/or torsion waves in the battery cell, having a propagation direction along the layers.

20. The method according to claim 17 wherein the evaluation comprises the parameters of an amplitude and a travel time of the signal.

21. The method according to claim 20, wherein a prognosis of the physical changes, preferably temperature changes, of the battery cell in the future is generated by evaluating the parameters over time.

22. The diagnostic device according to claim 1, further comprising a transmitter for arrangement on a housing and/or cell contact of the battery cell, wherein the transmitter is suitable for exciting the received acoustic plate waves and/or the acoustic torsion waves in the battery cell having a propagation direction along the layers.

23. The battery system according to claim 13, further comprising at least one transmitter for arrangement on a housing and/or cell contact of the battery cell, wherein the at least one transmitter is suitable for exciting the acoustic plate waves and/or the acoustic torsion waves having a propagation direction along the layers in the battery cell.
